(19) United States
(12) Patent Application Publication
(10) Pub. No.: US 2022/0260862 A1
(43) Pub. Date: Aug. 18, 2022

(54) Semiconductor Optical Modulator and Method of Manufacturing the Same

(71) Applicant: Nippon Telegraph and Telephone Corporation, Tokyo (JP)

(72) Inventors: Yoshihiro Ogiso, Musashino-shi, Tokyo (JP); Mitsuteru Ishikawa, Musashino-shi, Tokyo (JP); Nobuhiro Nunoya, Musashino-shi, Tokyo (JP)

(21) Appl. No.: 17/618,146

(22) PCT Filed: Jun. 26, 2019
(86) PCT No.: PCT/JP2019/025431

§ 371 Date: Dec. 10, 2021

(51) Int. Cl. G02F 1/017; G02F 1/21; G02F 1/225; G03F 7/00

(52) U.S. Cl. CPC G02F 1/01708; G02F 1/212; G02F 2202/101; G03F 7/0005; G02F 2202/102; G02F 1/2257

(57) ABSTRACT

In a semiconductor light modulator having a multiple quantum well structure, a light spot size converter element provided in a light input/output section is easily and accurately manufactured. At least one layer of a compound semiconductor layer containing a P element is inserted into a desired position in the multiple quantum well structure containing an Al element. This layer is smaller than a band gap of a compound semiconductor used in a bather layer of the multiple quantum well.

### TECHNICAL FIELD

An invention according to an embodiment of the present invention relates to a semiconductor light modulation element, and more particularly to an optical coupling technique between a light modulation element and an optical fiber.

### BACKGROUND ART

In recent years, light modulators using compound semiconductor materials have been actively researched and developed in the context of a reduction in size and an increase in speed of light modulators. In particular, a light modulator using InP as a substrate material is capable of highly efficient modulation operation by utilizing the quantum-confined Stark effect or the like in a communication wavelength band, and thus InP has attracted attention as a promising modulator material in place of conventional ferroelectric materials.

An InP-based light modulator is able to obtain highly efficient light modulation characteristics due to the quantum-confined Stark effect (QCSE), known as an electrooptical effect, by using a multipleb quantum well structure (MQW) for an optical waveguide core, and therefore many of the InP modulators employ a structure in which the MQW is taken as a core. The MQW of the InP-based modulator used for a communication wavelength (in particular, C-band, near 1.55 μm) is broadly classified into two types of material bases. One of them is an MQW containing Al atoms (hereinafter, referred to as an Al-based MQW) in which InAlAs or InGaAlAs is a barrier layer and InGaAlAs is a well layer, and the other one is an Al atom-free MQW (hereinafter, referred to as a P-based MQW) in which InP or InGaAsP is a barrier layer and InGaAsP or InGaAs is a well layer.

In general, since a conductor band offset (ΔEc) is larger in the Al-based MQW than that in the P-based MQW, a sharper band absorption edge can be obtained, thereby making it possible to perform highly efficient light modulation by QCSE. Therefore, the Al-based MQW has been adopted, in many cases, the high speed modulators in recent years.

Next, a light input/output section of the light modulation element will be described. In the InP-based light modulators, as described above, since the MQW is used as a core layer in many cases, a mode field MDF of light is determined approximately by the width and height of the MQW.

FIG. 1(a) illustrates a semiconductor light modulation element including a substrate 101, a clad layer 102, a lower n-type clad layer 103a on the clad layer 102, a core layer 104a on the lower n-type clad layer 103a, a clad layer 103b on the core layer 104a, and an upper clad layer 105 on the clad layer 103b. As illustrated in FIGS. 1(a) and 1(b), in the InP-type modulators, a so-called deep ridge optical waveguide structure is adopted in many cases in which light confinement in a lateral direction is air, and a mode field in the lateral direction can obtain a desired field relatively easily by controlling the width of the deep ridge waveguide. On the other hand, a mode field in a longitudinal direction is determined by a laminated semiconductor structure, and it is not easy to control the mode field in the longitudinal direction by manufacture processing. These features may apply to general planar lightwave circuits, and various optical spot size converters have been proposed to control the mode field in the longitudinal direction in optical devices (for example, Patent Literature (PTL) 1).

Since it is preferable for optical devices to be smaller in spot size in many cases, it is necessary to form a spot size converter (SSC) on an optical waveguide as needed in order to increase a spot size only in a localized area. Various structures and manufacturing methods for SSCs configured to locally expand spot sizes in optical waveguide-type optical devices have been present.

There are mainly two types of mechanisms for spot size conversion. One of them is an approach, as illustrated in FIGS. 1(a) and 1(b), in which a cross-sectional shape of the core layer 104a is reduced to let the light confined in a core layer 104b come out to the clad layers, and a mode field 106a is expanded to be a mode field 106b (for example, PTL 1). As illustrated in FIG. 1(c), the second one is an approach in which a mode field 106c is also expanded by not reducing, but expanding a cross-sectional shape of the core layer 104b (for example, Non Patent Literature (NPL) 1). In general, in the first approach, since the eigenmode of light approaches the cutoff, the spot size sensitively changes with respect to the waveguide shape perturbation, and therefore the manufacturing tolerance is low for the approach. An advantage of the second approach is such that an amount of change in geometric size of the waveguide necessary to obtain a fixed amount of change in spot size is allowed to be small.

### CITATION LIST

### Patent Literature

PTL 1: JP 6339965 B

### Non Patent Literature

NPL 1: http://citeseerx.ist.psu.edu/viewdoc/download?doi=10.1.1.628.5856&rep=repl&type=pdf

### SUMMARY OF THE INVENTION

### Technical Problem

In PTL 1, a dry etching device with high accuracy is necessary in order to effectively leverage a micro loading effect and obtain a uniform etching depth in the wafer surface, which raises a problem that the manufacturing environment is limited. Further, it may be difficult to stably obtain a depth on the order of several nanometers even in a case in which the depth is controlled by an internal monitor or the like during dry etching. Furthermore, because a hard mask of SiO₂ or the like is typically used in dry etching, there is a problem of an increase in manufacturing process to be additionally carried out, such as processing of SiO₂ or the like.

Thus, in order to solve the above problems, an object of an invention according to an embodiment of the present invention is to provide a spot size converter that is manufactured by a simple manufacturing apparatus, is stably etched with the accuracy on the order of several nanometers, and is able to shorten the manufacturing process.

### Means for Solving the Problem

An invention according to an embodiment of the present invention is conceived to provide a semiconductor light modulation element serving as a semiconductor light modulator including an InP-based compound semiconductor, wherein a waveguide core layer of the semiconductor light modulator includes an etching stop layer containing a P element, and a multiple quantum well structure located on the etching stop layer and containing an Al element, a bather layer is located over the etching stop layer and is provided in the multiple quantum well structure, and an energy band gap of the etching stop layer is smaller than a band gap of the bather layer.

The etching stop layer is inserted into a desired position (a position at which the etching is expected to be stopped) in a modulator core layer (including an MQW). When an MQW containing an Al element is used, it is desirable for the etching stop layer containing a P element. For example, in the case of an MQW in which InAlAs is a barrier layer and InGaAlAs is a well layer, InP or InGaAsP that can be lattice-matched with the above layers is used for the etching stop layer. It is desirable for the stop layer to have a smaller band gap than the barrier layer.

### Effects of the Invention

By using the invention according to an embodiment of the present invention, it is possible to manufacture an optical spot size converter provided in a light input/output section of a semiconductor light modulation element in a shorter time and with higher accuracy (the overall layer thickness can be controlled on the order of several nanometers) than the conventional art, without impairing light transmittance and light modulation characteristics (quenching characteristics) of the overall light modulation element.

### BRIEF DESCRIPTION OF DRAWINGS

FIG. 1(a) is a diagram illustrating an image of MFD expansion by thinning a film thickness of an MQW core. FIG. 1(b) is a diagram illustrating an image of MFD expansion by thinning a film thickness of an MQW core. FIG. 1(c) is a diagram illustrating an image of moving an optical mode to a second core.

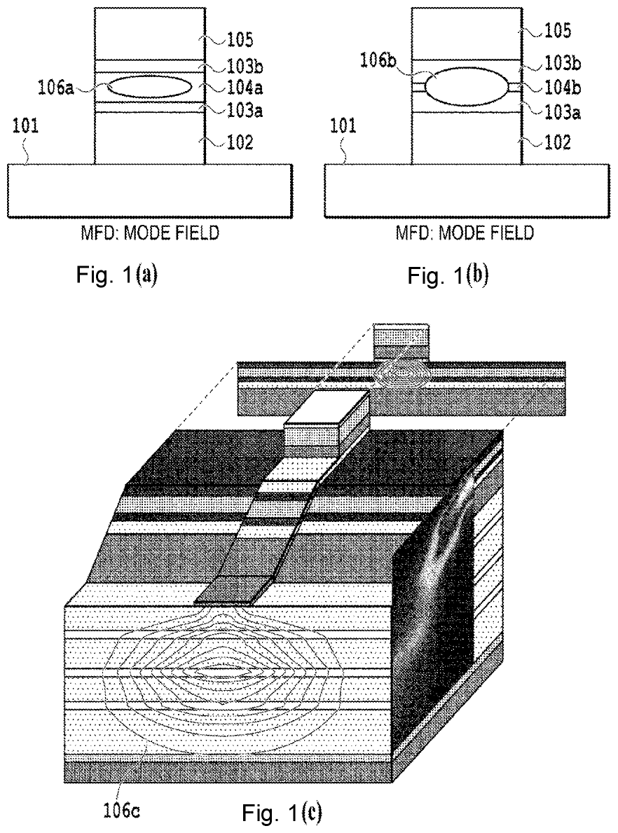

FIG. 2(a) is a top view of a semiconductor light modulation element according to a first embodiment, FIG. 2(b) is a diagram illustrating a layer structure in a region (b), FIG. 2(c) is a diagram illustrating a layer structure in a region (c), and FIG. 2(d) is a diagram illustrating a layer structure in a region (d).

FIG. 3(a) is a diagram describing patterning of an MQW structure. FIG. 3(b) is a diagram illustrating a step-shaped MQW structure in FIG. 2(d). FIG. 3(c) is a diagram illustrating a configuration of an MQW structure. FIG. 3(d) is a diagram illustrating movement of an optical mode from an upper MQW structure to a lower MQW structure.

FIG. 4 is a diagram illustrating dependence of light modulation characteristics on presence/absence of an etch stop layer.

FIG. 5(a) illustrates a top view of an SSC region of a semiconductor light modulation element according to a second embodiment, FIG. 5(b) illustrates a cross-sectional view of an SSC region in a cross section (b), FIG. 5(c) illustrates a cross-sectional view of an SSC region in a cross section (c), and FIG. 5(d) illustrates a cross-sectional view of an SSC region in a cross section (d).

### DESCRIPTION OF EMBODIMENTS

Embodiments of the present invention will be described with reference to the accompanying drawings. The embodiments described below are embodiments of the present invention, and the present invention is not limited to the following embodiments.

### First Embodiment

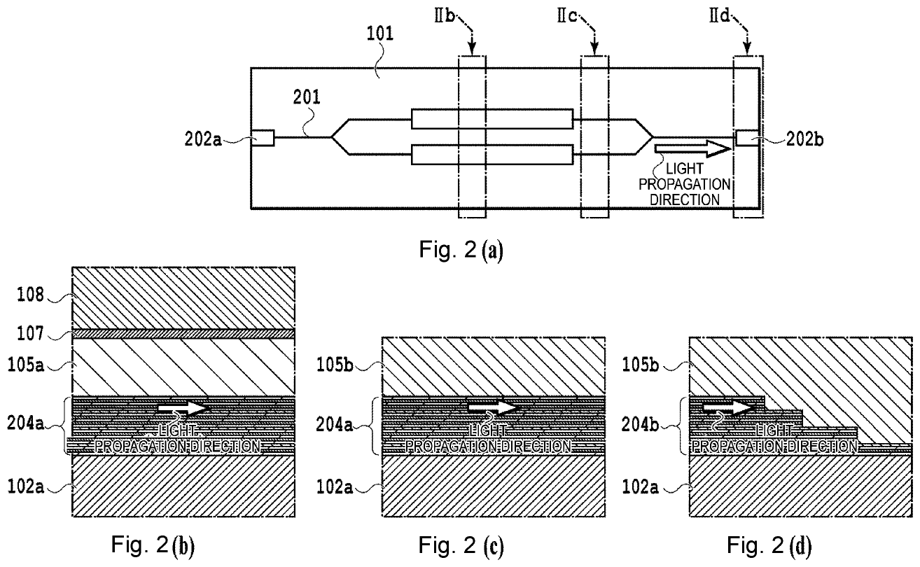

FIG. 2 illustrates a conceptual diagram of a semiconductor Mach-Zehnder light modulator (MZM) according to a first embodiment of the present invention. FIG. 2(a) is a top view of a semiconductor light modulation element according to the first embodiment, FIG. 2(b) is a diagram illustrating a layer structure in a region (b), FIG. 2(c) is a diagram illustrating a layer structure in a region (c), and FIG. 2(d) illustrates a layer structure in a region (d). As illustrated in FIG. 2(a), regions of an SSC 202a and an SSC 202b to be coupled via a waveguide 201 are provided on an InP substrate 101.

The substrate uses the semi-insulating InP substrate 101 doped with Fe, for example, as a compound semiconductor crystal of a zinc blende type. An n-type contact clad layer, a non-doped core clad layer, and a p-type clad contact layer are laminated in that order from the substrate 101 surface by epitaxial growth. The n-type contact clad layer corresponds to a lower clad layer 102, the non-doped core clad layer corresponds to a multiple quantum well (MQW) structure 204a, and the p-type clad contact layer corresponds to an upper p-type clad layer 105a. As illustrated in FIG. 2(a), an upper p-type contact layer 107 is provided on the upper p-type clad layer 105a, and an electrode 108 is provided on the upper p-type contact layer 107. As illustrated in FIG. 2(b), an upper i-type clad layer 105b is provided on the MQW structure 204a.

A multiple quantum well (MQW) structure 204b (PL wavelength: 1.4 μm) constituted of a period of InGaAlAs/InAlAs was used in the core layer in order to efficiently use a refractive index change due to the electrooptical effect with respect to a 1.5 μm band wavelength.

When an MQW containing an Al element is used, it is desirable for the etching stop layer containing a P element. For example, in the case of an MQW in which InAlAs is a barrier layer and InGaAlAs is a well layer, InP or InGaAsP that can be lattice-matched with the above layers is used for the etching stop layer. It is desirable for the stop layer to have a smaller band gap than the barrier layer.

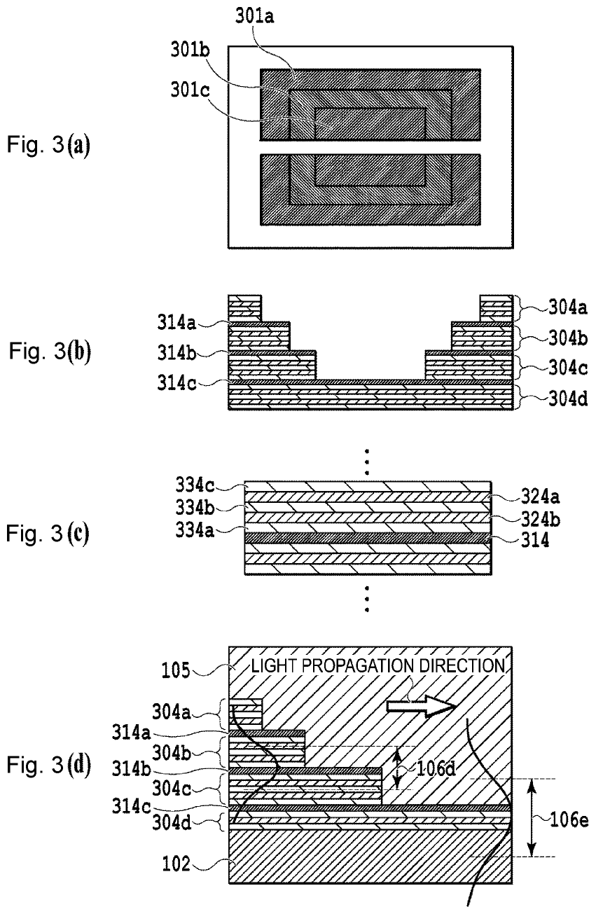

As illustrated in FIG. 2(d), when forming the spot size converters (SSCs) 202a and 202b of a light input/output region, at least one etching stop layer capable of selective etching is inserted to facilitate processing to a desired depth by chemical wet etching. In the present embodiment, as illustrated in FIG. 3(b), a total of three layers of etching stop layers 314a to 314c were inserted into desired positions to form an MQW 204b in a step shape with four steps in order to perform optical mode expansion adiabatically in the SSC regions 202a and 202b (without deterioration in optical characteristics). The etching stop layers 314a to 314c were composed of P elements having etching selectivity with respect to the MQW formed of Al elements and being lattice-matched with the MQW. Specifically, InP was used as the etching stop layer. By switching not from InGaAlAs, but from InAlAs (barrier layer) to InP, the number of types of gases was decreased at the time of gas switching during crystal growth, and the mixed crystals of the switching interface were minimized. It is apparent that the usefulness of the invention according to the embodiment of the present invention is not lost even when the number of layers of etching stop layers is not limited to three, and around two to five layers thereof are set, for example.

A heterostructure of a p-i-n type from above is used in the present embodiment, but the invention according to the embodiment of the present invention exhibits its effects when the waveguide includes etching stop layers in the MQW structure, and therefore it is apparent that even a heterostructure in which, for example, n-i-p, n-p-i-n, and n-i-p-n are laminated in that order from above causes no problem. The clad layer was composed of InP having a lower refractive index than the core layer, for example, and InGaAs being lattice-matched with InP and having a small energy band gap was used for the p-type contact layer. The doping concentrations of the n-type clad layer and the p-type clad layer were both 1×10¹⁸ cm⁻³, and the doping concentration of InGaAs was 1×10¹⁹ cm³.

It is only required that the compositions of the core and the clad each have a relative refractive index difference, and therefore InGaAlAs and the like having different compositions may be used in the core clad layer, the n-type clad layer, and the p-type clad layer, for example.

The wavelength is not limited to the 1.5 μm band, and even when a 1.3 μm band is used, the usefulness of the invention according to the embodiment of the present invention will not be lost.

To form electro-separation between electrodes and an SSC structure, the p contact layer and the p clad layer in the regions other than the light modulation region are removed by dry etching and chemical etching. Subsequently, photoresist patterning is performed in the SSC regions 202a and 202b by using a first mask pattern (opening) 301a to form a first MQW 304a of a first step (the uppermost step of the four steps). Thereafter, the first MQW 304a is wet-etched down to the first etching stop layer 314a. An etchant containing hydrogen peroxide and having a high etching rate difference between Al and P elements was used as an etching liquid. Subsequently, in a similar manner, after forming a resist pattern by using a second mask pattern (opening) 301b, etching of the first etching stop layers 314a and a second MQW 304b is performed. The opening of the second mask pattern 301b is smaller than the opening of the first mask pattern 301a. A hydrochloric acid-based etchant was used for the etching stop layer. Finally, similar processing is performed with respect to a third mask pattern 301c so as to pattern a third MQW 304c. The opening of the third mask pattern 301c is smaller than the opening of the second mask pattern 301b. Consequently, only the third etching stop layer 314c and a fourth MQW 304d are left. The film thickness of the fourth MQW 304d is controlled by crystal growth, which makes it possible to control the thickness on the order of nanometers. In the present example, the thickness of the fourth MQW 304d was set to be 100 nm, for example, but it is unnecessary to limit the thickness to 100 nm because the thickness thereof differs depending on the desired mode field. It is possible to obtain the spot size converter (SSC) 202b in FIG. 2(d) by dividing the area at the vicinity of the center of FIG. 3(b).

After the processing of the MQW in the SSC region is completed, a non-doped clad layer 105 (here, InP was used) is deposited by crystal regrowth, for example. An Fe-doped clad layer may be used instead of the non-doped clad layer.

When the light modulation region and the light input/output region are configured to have different cores, a complicated manufacturing process needs to be additionally performed, and therefore it is preferable to have the MQW cores constituted of the same composition.

FIG. 3(c) is an enlarged view of 204b in FIG. 2(d). As illustrated in FIG. 3(c), the MQW structures 304a to 304c each include a partition layer 334a on an etching stop layer 314, a well layer 324b on the partition layer 334a, a partition layer 334b on the well layer 324b, a well layer 324a on the partition layer 334b, and a partition layer 334c on the well layer 324a.

FIG. 3(d) is an enlarged view of FIG. 2(d). As light travels in the light propagation direction, a mode field 106d expands toward a mode field 106e.

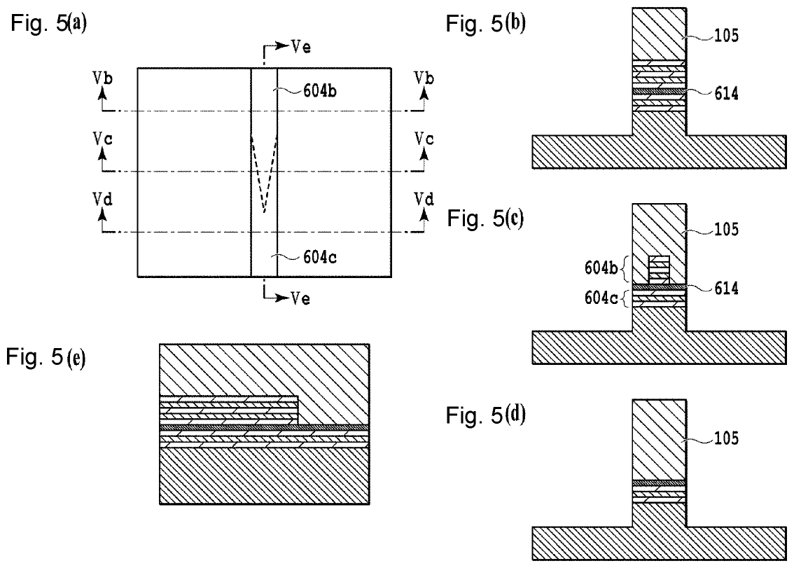

Subsequently, the Mach-Zehnder (MZ) interference waveguide 201 is formed by dry etching using a SiO₂ mask, as illustrated in FIG. 2(a). A deep ridge waveguide structure is constituted as in FIG. 5 to be described later. Thereafter, unevenness of the waveguide is flattened by an organic film such as polyimide or benzocyclobutene (BCB), and electrode patterning is performed thereon to form the electrode 108, as illustrated in FIG. 2(b), by using an Au plating method or the like. Here, a traveling wave type distributed constant electrode is used for high speed operation. More desirably, the use of a capacitance loading type traveling wave electrode having a high degree of freedom in design of characteristic impedance, microwave speed, and the like makes it possible to obtain a higher speed.

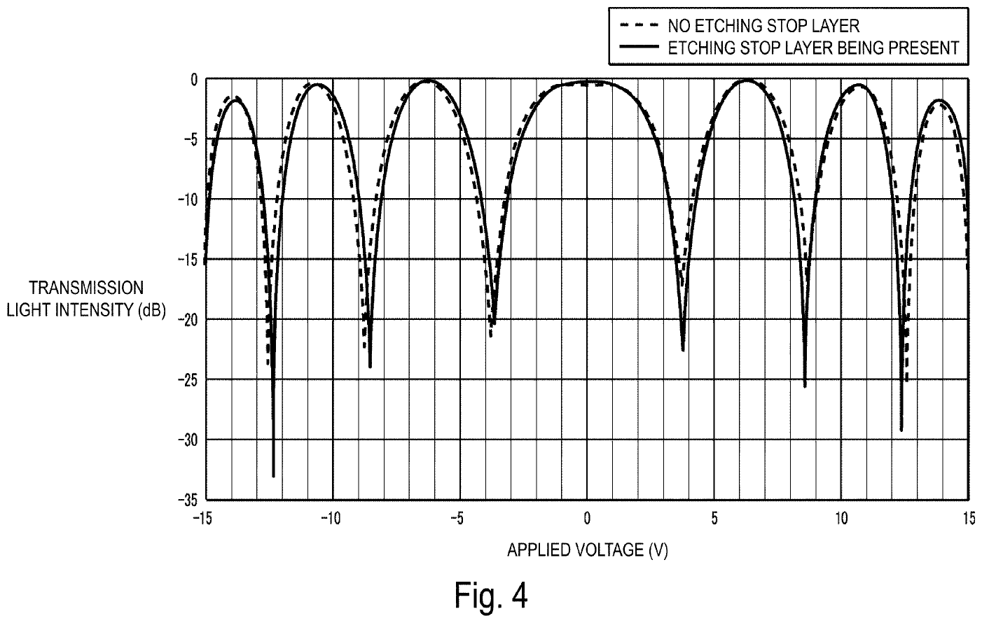

As illustrated in FIG. 4, it has been experimentally confirmed that no deterioration in light modulation characteristics occurs due to the presence or absence of insertion of an etching layer. The absence of insertion of the etching layer corresponds to a dotted line, and the presence of insertion of the etching layer corresponds to a solid line in the drawing, where a clear difference has not been found between the presence and absence of insertion of the etching layer.

### Second Embodiment

FIGS. 5(a) to 5(d) illustrate a conceptual diagram of a semiconductor Mach-Zehnder light modulator (MZM) according to a second embodiment of the present invention. Processing until the removal of the upper contact and clad layers in the regions other than the modulation region is the same as that of the first embodiment, and only SSC processing is different from that of the first embodiment. A stop layer in an MQW is only one in number, and it is inserted into a position of the thickness of the MQW where final processing is performed. The stop layer in the above MQW corresponds to the third etching stop layer 314c described in the first embodiment. The composition of an etching stop layer 614 uses, for example, InP or InGaAsP containing a P element. Here, InP was used. After the removal of the upper clad layer, a photoresist is used to form a tapered pattern, as illustrated in FIG. 5(a), and an upper MQW 604b is etched down to the etching stop layer 614 by using the tapered pattern. All the etching may be performed by wet etching, or dry etching may be performed halfway and the processing may be finally carried out down to the etching stop layer 614 by wet etching. Thereafter, a clad layer 105, which may be non-doped or Fe-doped, is deposited by crystal regrowth. In the second embodiment, InP is used for the clad layer 105. This configuration reduces only the width of the upper MQW 604b and can move an optical mode to a lower MQW 604c.

Chemical wet etching is used to simplify the processing apparatus and shorten the processing.

1. A semiconductor light modulation element serving as a semiconductor light modulator including an InP-based compound semiconductor,
wherein a waveguide core layer of the semiconductor light modulator includes,
an etching stop layer containing a P element, and
a multiple quantum well structure located on the etching stop layer and containing an Al element,
a barrier layer is located over the etching stop layer, the barrier layer is provided in the multiple quantum well structure, and
an energy band gap of the etching stop layer is smaller than a band gap of the barrier layer.

2. The semiconductor light modulation element according to claim 1,
wherein the barrier layer contains InAlAs, and a well layer in the multiple quantum well structure is located over the barrier layer and contains InGaAlAs.

3. The semiconductor light modulation element according to claim 1, wherein the etching stop layer contains InP or InGaAsP.

4. The semiconductor light modulation element according to claim 1, wherein a plurality of the etching stop layers are exposed in different regions and formed in a step shape.

5. The semiconductor light modulation element according to claim 1, wherein an optical waveguide structure in a spot size converter (SSC) region where the plurality of etching stop layers are exposed in different regions and formed in a step shape takes a deep ridge structure.

6. The semiconductor light modulation element according to claim 1,
wherein a light input/output section of the semiconductor light modulation element is provided with an optical spot size converter, and
the optical spot size converter includes a structure in which the waveguide core layer is etched to the etching stop layer to have a thinned film thickness.

7. A manufacturing method for a semiconductor light modulation element in which a plurality of etching stop layers are exposed in different regions and formed in a step shape, the manufacturing method comprising:
forming a first MQW structure containing an Al element;
forming an etching stop layer containing a P element on the first MQW structure;
forming a second MQW structure containing an Al element on the etching stop layer; and
patterning the second MQW structure to make the etching stop layer exposed.

8. The semiconductor light modulation element according to claim 2, wherein the etching stop layer contains InP or InGaAsP.

9. The semiconductor light modulation element according to claim 2, wherein a plurality of the etching stop layers are exposed in different regions and formed in a step shape.

10. The semiconductor light modulation element according to claim 3, wherein a plurality of the etching stop layers are exposed in different regions and formed in a step shape.

11. The semiconductor light modulation element according to claim 2, wherein an optical waveguide structure in a spot size converter (SSC) region where the plurality of etching stop layers are exposed in different regions and formed in a step shape takes a deep ridge structure.

12. The semiconductor light modulation element according to claim 3, wherein an optical waveguide structure in a spot size converter (SSC) region where the plurality of etching stop layers are exposed in different regions and formed in a step shape takes a deep ridge structure.

13. The semiconductor light modulation element according to claim 4, wherein an optical waveguide structure in a spot size converter (SSC) region where the plurality of etching stop layers are exposed in different regions and formed in a step shape takes a deep ridge structure.

14. The semiconductor light modulation element according to claim 2,
wherein a light input/output section of the semiconductor light modulation element is provided with an optical spot size converter, and
the optical spot size converter includes a structure in which the waveguide core layer is etched to the etching stop layer to have a thinned film thickness.

15. The semiconductor light modulation element according to claim 3,
wherein a light input/output section of the semiconductor light modulation element is provided with an optical spot size converter, and
the optical spot size converter includes a structure in which the waveguide core layer is etched to the etching stop layer to have a thinned film thickness.

16. The semiconductor light modulation element according to claim 4,
wherein a light input/output section of the semiconductor light modulation element is provided with an optical spot size converter, and
the optical spot size converter includes a structure in which the waveguide core layer is etched to the etching stop layer to have a thinned film thickness.
